(19) United States
(12) Patent Application Publication
(10) Pub. No.: US 2024/0213054 A1
(43) Pub. Date: Jun. 27, 2024

(54) METHOD AND COMPUTING SYSTEM FOR MANUFACTURING THREE-DIMENSIONAL SEMICONDUCTOR DEVICE

(71) Applicant: SAMSUNG ELECTRONICS CO., LTD., Suwon-si (KR)

(72) Inventors: Youngsik OH, Suwon-si (KR); Sunghoon KIM, Suwon-so (KR)

(73) Assignee: SAMSUNG ELECTRONICS CO., LTD., Suwon-si (KR)

(21) Appl. No.: 18/381,032

(22) Filed: Oct. 17, 2023

(30) Foreign Application Priority Data
Dec. 22, 2022 (KR) 10-2022-0182167

(51) Int. Cl. H01L 21/67

(52) U.S. Cl. CPC H01L 21/67138; H01L 21/67276; H01L 21/67294

(57) ABSTRACT

A method and a computing system, for manufacturing a three-dimensional semiconductor device including first and second semiconductor device layers, are provided. The method includes: identifying candidate locations in a via area of the first semiconductor layer; identifying nets of the second semiconductor layer to be connected to through-via structures corresponding to the candidate locations; identifying a plurality of connection costs respectively corresponding to connections between the through-via structures and the nets; identifying pairs of the nets and the through-via structures, based on the plurality of connection costs; allocating the through-via structures according to the pairs; forming the through-via structures at the candidate locations; and forming electrical connections between the through-via structures.

### CROSS-REFERENCE TO RELATED APPLICATION

This application claims priority under to Korean Patent Application No. 10-2022-0182167, filed on Dec. 22, 2022, in the Korean Intellectual Property Office, the disclosure of which is incorporated by reference herein in its entirety.

### BACKGROUND

The present disclosure relates to a method and a computing system, for manufacturing a three-dimensional semiconductor device, and more particularly, to a method and a computing system, which are for manufacturing a three-dimensional semiconductor device including a through-via structure connecting a first semiconductor layer to a second semiconductor layer of a stacked structure.

Among semiconductor devices, memory devices are used to store data and are classified into volatile memory devices and nonvolatile memory devices. According to the demand for high capacity and miniaturization of nonvolatile memory devices, a three-dimensional memory device in which a memory cell array and peripheral circuits are arranged in a vertical direction has been developed. Among semiconductor devices, a system semiconductor device has also been developed to be implemented with a plurality of vertically arranged chips, in accordance with the demand for miniaturization.

### SUMMARY

One or more embodiments provide a method and a computing system for manufacturing a three-dimensional semiconductor device including through-via structures disposed in consideration of routing suitability.

According to an aspect of an embodiment, a method of manufacturing a semiconductor device including a first semiconductor layer and a second semiconductor layer which are stacked, includes: identifying candidate locations in a via area of the first semiconductor layer; identifying nets of the second semiconductor layer to be connected to through-via structures corresponding to the candidate locations; identifying a plurality of connection costs respectively corresponding to connections between the through-via structures and the nets; identifying pairs of the nets and the through-via structures, based on the plurality of connection costs; allocating the through-via structures according to the pairs; forming the through-via structures at the candidate locations; and forming electrical connections between the through-via structures and the nets.

According to another aspect of an embodiment, a method of manufacturing a semiconductor device including a through-via structure connecting an upper wiring pattern and a lower wiring pattern, which constitute a first net, to each other, includes: identifying candidate locations in a via area of the semiconductor device; identifying nets to be connected to through-via structures corresponding to the candidate locations; identifying a plurality of connection costs respectively corresponding to connections between the through-via structures and the nets; identifying pairs of the nets and the through-via structures, based on the plurality of connection costs; and forming the through-via structures to connect the upper wiring pattern and the lower wiring pattern to each other according to the pairs.

According to another aspect of an embodiment, a computing system for manufacturing a semiconductor device including a first semiconductor layer and a second semiconductor layer, which are stacked, includes: a memory storing a program; and a processor configured to access the memory and execute the program to control the computing system to: identify candidate locations in a via area of the first semiconductor layer; identify nets of the second semiconductor layer to be connected to through-via structures corresponding to the candidate locations; identify a plurality of connection costs respectively corresponding to connections between the through-via structures and the nets; identify pairs of the nets and the through-via structures, based on the plurality of connection costs; allocate the through-via structures according to the pairs; form the through-via structures at the candidate locations; and form electrical connections between the through-via structures and the nets.

### BRIEF DESCRIPTION OF DRAWINGS

The above and other objects and features will be more clearly understood from the following description of embodiments, taken in conjunction with the accompanying drawings, in which:

FIG. 1 is a diagram schematically illustrating a structure of a semiconductor device according to an embodiment;

FIG. 2 is a diagram for explaining a connection relationship between a through-via structure formed in a via area and a net according to an embodiment;

FIGS. 3, 4A, and 4B are flowcharts illustrating a method of manufacturing a semiconductor device according to an embodiment;

FIG. 5 is a diagram for explaining an example of a modeling method for calculating a connection cost in operation S20 of FIG. 3 according to an embodiment;

FIGS. 6 and 7 are views for explaining a method for determining optimized matching pairs in operation S30 of FIG. 3 according to an embodiment;

FIG. 8 is a block diagram illustrating a memory device as an example of a semiconductor device 10 according to an embodiment;

FIG. 9 schematically illustrates the structure of a memory device as an example of a semiconductor device according to an embodiment;

FIG. 10 is a circuit diagram illustrating a memory block according to an embodiment;

FIG. 11A is a perspective view illustrating a memory block according to an embodiment;

FIG. 11B is a perspective view illustrating a memory block according to an embodiment;

FIG. 12 is a diagram illustrating a memory device that is a semiconductor device according to an embodiment;

FIG. 13 is a cross-sectional view taken along line A-A′ of FIG. 12 according to an embodiment;

FIG. 14 is a schematic diagram illustrating an image sensor as a semiconductor device according to an embodiment; and

FIG. 15 is a block diagram illustrating a computing system including a memory storing a program according to an embodiment.

### DETAILED DESCRIPTION

Hereinafter, embodiments will be described in detail with reference to the accompanying drawings. Each embodiment provided in the following description is not excluded from being associated with one or more features of another example or another embodiment also provided herein or not provided herein but consistent with the present disclosure. As used herein, the term “and/or” includes any and all combinations of one or more of the associated listed items. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

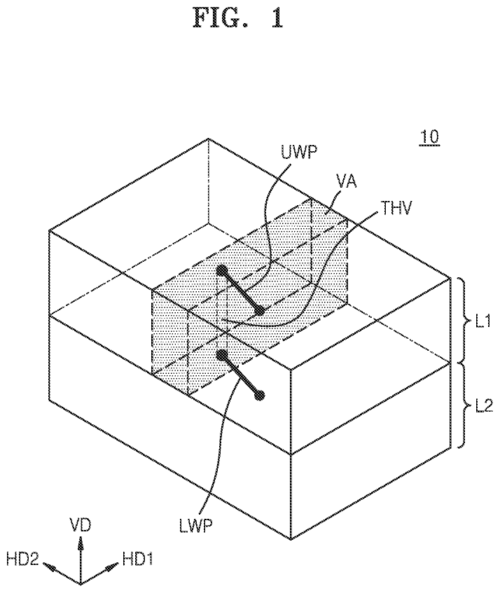

FIG. 1 is a diagram schematically illustrating a structure of a semiconductor device 10 according to an embodiment.

Referring to FIG. 1, the semiconductor device 10 may include a first semiconductor layer L1 and a second semiconductor layer L2, and the first semiconductor layer L1 may be stacked on the second semiconductor layer L2 in a direction VD perpendicular to the second semiconductor layer L2. That is, the second semiconductor layer L2 may be disposed below the first semiconductor layer L1 in a vertical direction. Because the semiconductor device 10 is formed as a stacked structure of a plurality of semiconductor layers, the first semiconductor layer L1, and the second semiconductor layer L2, areas in the horizontal directions HD1 and HD2 may be effectively reduced, and the degree of integration of the semiconductor device 10 may be improved.

In an embodiment, the semiconductor device 10 may include the first semiconductor layer L1 and the second semiconductor layer L2 formed on one semiconductor chip. In another embodiment, each of the first semiconductor layer L1 and the second semiconductor layer L2 is formed, and the semiconductor device 10 may be manufactured by combining the first semiconductor layer L1 and the second semiconductor layer L2 through Cu to Cu (C2C) wafer bonding. For example, a plurality of bonding pads may be formed on the first surface of the first semiconductor layer L1, and a plurality of bonding pads may be formed on the first surface of the second semiconductor layer L2. The plurality of bonding pads of the first semiconductor layer L1 and the plurality of bonding pads of the second semiconductor layer L2 may be connected to each other. Each of the first semiconductor layer L1 and the second semiconductor layer L2 may be implemented as a separate chip.

The semiconductor device 10 may include a via area VA in which through-via structures are disposed. The first semiconductor layer L1 and the second semiconductor layer L2 may be electrically connected to each other through through-via structures THV formed in the through-via hole. For example, the through-via structure THV may be formed to connect the upper wiring pattern UWP of the first semiconductor layer L1 and the lower wiring pattern LWP of the second semiconductor layer L2 to each other. For example, the through-via structure THV may be formed to connect the upper wiring pattern UWP of the first semiconductor layer L1 and the bonding pad of the first semiconductor layer L1 to each other, so that the upper wiring pattern UWP of the first semiconductor layer L1 and the lower wiring pattern LWP connected to the bonding pad of the second semiconductor layer L2 may be electrically connected. The upper wiring pattern UWP and the lower wiring pattern LWP may form one net. In this case, the net may refer to, for example, a configuration including a plurality of input/output pins of the circuit components and wires electrically connecting the input/output pins. That is, the net may refer to components constituting one node through which the same signal is received/transmitted.

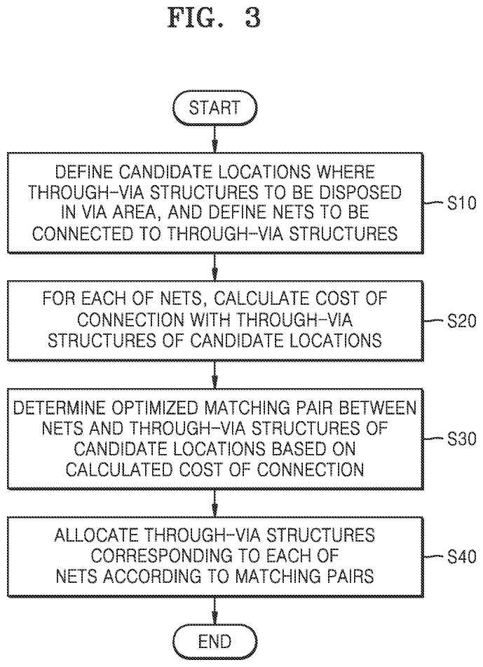

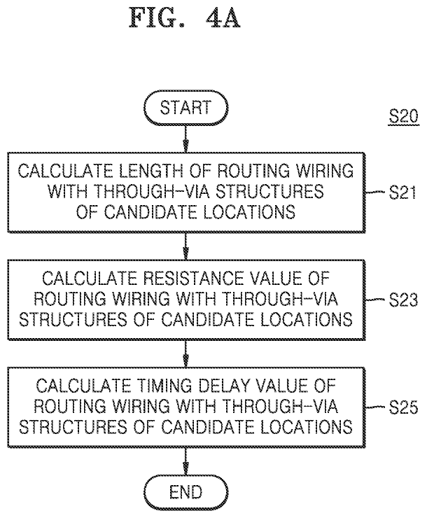

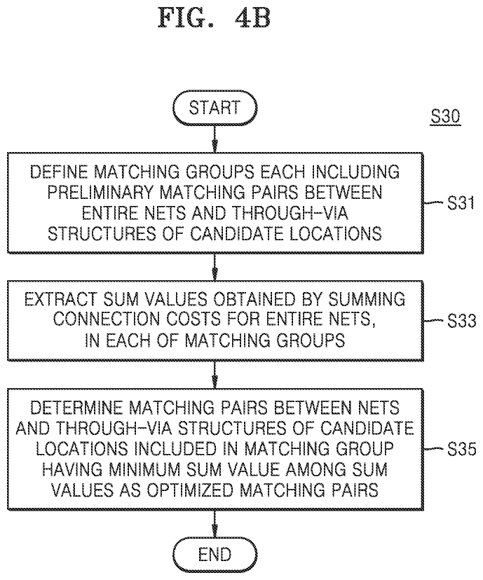

The through-via structure THV may be formed to connect the upper wiring pattern UWP of the first semiconductor layer L1 and the lower wiring pattern LWP of the second semiconductor layer L2 to each other according to the manufacturing method of the semiconductor device to be described with reference to FIGS. 3, 4A and 4B.

In an embodiment, the semiconductor device 10 may be a memory device, for example, a nonvolatile memory device. Alternatively, in an embodiment, the semiconductor device 10 may be a system semiconductor device other than a non-memory device, such as an image sensor. In some embodiments, the semiconductor device 10 may include a system semiconductor device, such as an image sensor, as well as a nonvolatile memory device.

The method and computing system for manufacturing a three-dimensional semiconductor device according to embodiments may dispose a through-via structure connecting the first semiconductor layer and the second semiconductor layer of the stacked structure to each other in consideration of routing suitability. That is, when allocating nets of the second semiconductor layer to be connected to each of the through-via structures, routing suitability may be considered. Accordingly, routing for connecting the through-via structure to the net is facilitated, and timing characteristics of signals transmitted through the through-via structure may be prevented from deteriorating due to unnecessary detour routing.

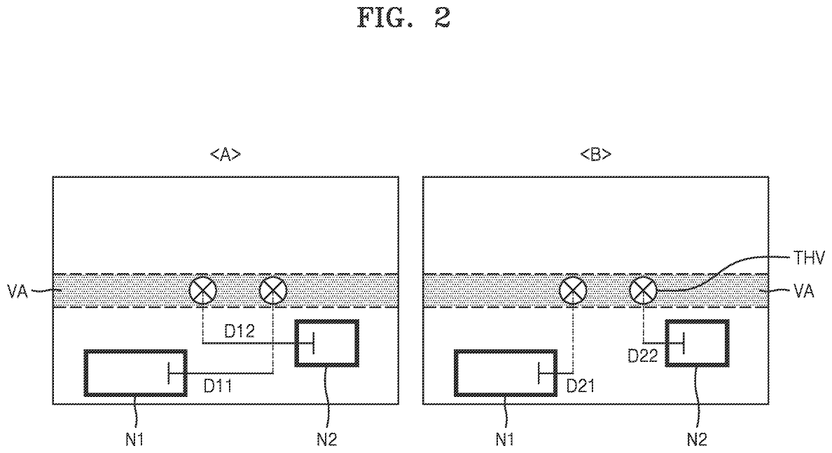

FIG. 2 is a diagram for explaining a connection relationship between a through-via structure formed in a via area and a net according to an embodiment. The drawing of FIG. 2 is a diagram explaining arrangement positions of wiring patterns constituting a certain net of the second semiconductor layer L2 and through-via structures in different configurations.

Referring to FIGS. 1 and 2, the through-via structures THV disposed in the via area VA may be connected to corresponding nets (e.g., a first net N1 and a second net N2).

At this time, according to the connection relationship between the through-via structures THV and the nets N1 and N2, the length of a routing wire connecting the through-via structures THV to the nets N1 and N2 may vary. For example, the length of the routing wire in configuration A may be calculated as D11+D12. Also, for example, the length of the routing wire in configuration B may be calculated as D21+D22. Because the through-via structures THV and nets disposed relatively close to each other are connected to each other, in configuration B, the length of the routing wire may be shorter than that of configuration A.

As the routing wires in the horizontal directions HD1 and HD2 become longer, routing congestion in the second semiconductor layer L2 may increase. As a result, the possibility of forming a routing detour in the second semiconductor layer L2 may increase. The routing detour may cause a resistance to increase, as well as a skew or delay of the signal transmitted to the net. Therefore, it may be required to connect the through-via structure THV to the net at a position capable of minimizing routing wires in the horizontal direction.

FIGS. 3, 4A, and 4B are flowcharts illustrating a method of manufacturing a semiconductor device according to an embodiment.

As described in FIG. 1, the semiconductor device may include a first semiconductor layer L1 and a second semiconductor layer L2, and the through-via structures may electrically connect the wirings of the first semiconductor layer L1 and the second semiconductor layer L2 to each other.

Referring to FIGS. 3, 4A and 4B, in operation S10, candidate locations where through-via structures may be disposed in a via area may be defined, and nets to be connected to the through-via structures may be defined. Operation S10 may be performed with reference to netlist data.

In operation S20, for each of the nets, a cost of connection with through-via structures of candidate locations may be calculated. Operation S20 may include at least one of operations S21 to S25. That is, some of operations S21 to S25 may not be performed, and operations S21 to S25 may all be performed.

In operation S21, it is possible to calculate the length of routing wiring with through-via structures of candidate locations, and in operation S23, it is possible to calculate the resistance value of routing wiring with through-via structures of candidate locations, and in operation S25, it is possible to calculate a timing delay value of routing wiring with through-via structures of candidate locations. That is, the connection cost of the through-via structure of the candidate location for each of the nets may be calculated as the length of routing wiring with the through-via structure, be calculated as a resistance value of routing wiring with a through-via structure, or be calculated as a timing delay value of routing wiring with a through-via structure. The resistance value and the timing delay value may vary depending on the length of the routing wiring, the area of the cross section, and the constituent material.

In operation S30, an optimized matching pair of net and through-via structures between nets and through-via structures of candidate locations may be determined based on the calculated connection cost. In an embodiment, operation S30 may be performed using a Hungarian Algorithm. Operation S30 may include operations S31 to S35.

In operation S31, matching groups each including preliminary matching pairs between all of the nets and through-via structures of the candidate locations may be defined. In operation S33, sum values obtained by summing connection costs of all nets may be extracted from each of the defined matching groups. In operation S35, matching pairs between nets and through-via structures of candidate locations included in a matching group having a minimum sum value among sum values may be determined as optimized matching pairs. For example, matching pairs included in a matching group for which the total sum of the lengths of routing wirings with through-via structures for all nets becomes a minimum value, matching pairs included in a matching group in which the total sum of resistance values of routing wirings with through-via structures for all nets is minimized, or matching pairs of a matching group in which a total sum of timing delay values of routing wirings with through-via structures for all nets is minimized may be determined as optimized matching pairs.

In some embodiments, unlike operations S31 to S35 described in FIG. 4B, in operation S33, multiplication values obtained by multiplying connection costs for all nets may be extracted from each of the defined matching groups, and in operation S35, matching pairs between nets and through-via structures of candidate locations included in a matching group having a minimum multiplication value among multiplication values may be determined as optimized matching pairs.

In operation S40, contact structures corresponding to each of the nets may be allocated according to the determined matching pairs. Accordingly, through-via structures may be disposed and connected to corresponding nets in consideration of suitability of routing. Therefore, routing for connecting the through-via structure to the net may be facilitated, and timing characteristics of signals transmitted through the through-via structure may be prevented from deteriorating due to unnecessary detour routing.

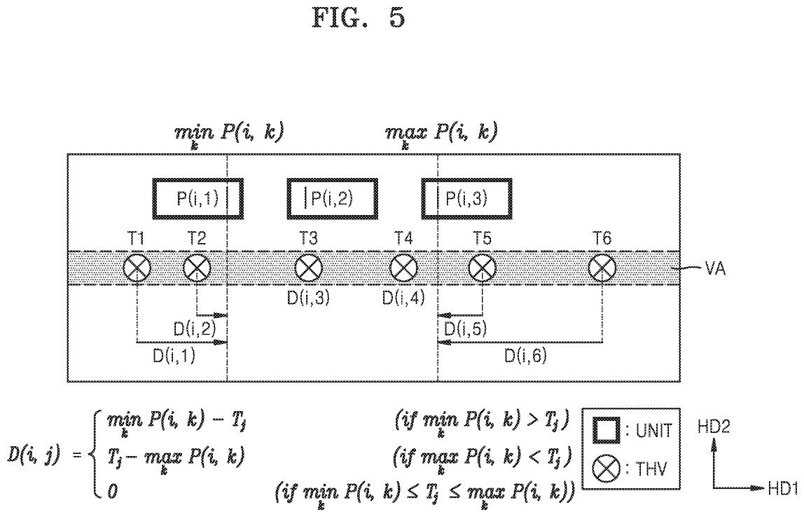

FIG. 5 is a diagram for explaining an example of a modeling method for calculating a connection cost in operation S20 of FIG. 3. according to an embodiment The diagram of FIG. 5 is a diagram explaining units that are wiring patterns constituting a certain net of the second semiconductor layer L2 and candidate locations in which through-via structures may be disposed.

Referring to FIG. 5, candidate locations Tj (i.e., T1, T2, T3, T4, T5 and T6) may be identified for through-via structures THV to be disposed in a via area VA. The via area VA may be relatively long in the first horizontal direction HD1 and relatively short in the second horizontal direction HD2. That is, candidate locations Tj in which through-via structures THV may be disposed may be defined side by side along the first horizontal direction HD1, and may refer to coordinates in the first horizontal direction HD1. For example, a first candidate location where through-via structures THV may be placed is T1, a second candidate location may be T2, a third candidate location may be T3, a fourth candidate location may be T4, a fifth candidate location may be T5, and a sixth candidate location may be T6.

Coordinates of units constituting a certain i-th net in the first horizontal direction HD1 may be P(i,k). For example, the coordinates of the first unit constituting a certain i-th net may be P(i,1), the coordinates of the second unit may be P(i,2), and the coordinates of the third unit may be P(i,3).

D(i,j), which is the connection cost of the through-via structure of the j-th candidate location for the i-th net, may be calculated by Equation 1 below. Because through-via structures THV disposed in the via area VA may be disposed side by side along the first horizontal direction HD1, and the position difference of the candidate locations Tj in the second horizontal direction HD2 is relatively small, in Equation 1 below, by calculating the distance difference in the first horizontal direction HD1 as the length of the predicted routing wiring, D(i,j), which is the connection cost of the through-via structure of the j-th candidate location for the i-th net, may be calculated.

$$[ Equation 1 ]$$

$$D ( i , j ) = \{ \begin{matrix}{min}_{k} P ( i , k ) - {T}_{i} & ( if {min}_{k} P ( i , k ) > {T}_{i} ) \\ {T}_{i} = {max}_{k} P ( i , k ) & ( if {max}_{k} P ( i , k ) < {T}_{i} ) \\ 0 & ( if {min}_{k} P ( i , k ) \leq {T}_{i} \leq {max}_{k} P ( i , k ) )\end{matrix}$$

At this time,

$${min}_{k} P ( i , k )$$

may refer to the coordinates of the leftmost unit with respect to the first horizontal direction HD1 among the units constituting the i-th net, and

$${max}_{k} P ( i , k )$$

may refer to the coordinates of a unit disposed at the rightmost side with respect to the first horizontal direction HD1 among units constituting the i-th net.

According to Equation 1, D(i,3) and D(i,4) may have a value of 0, and D(i,1) and D(i,2) may have values of

$${min}_{k} P ( i , k ) - T 1$$

$$and$$

$${min}_{k} P ( i , k ) - T 2 ,$$

respectively. In addition, D(i,5) and D(i,6) may have the values of

$$T 5 - {max}_{k} P ( i , k )$$

$$and$$

$$T 6 - {max}_{k} P ( i , k ) ,$$

respectively. The calculated connection cost D(i,j) of the through-via structures of the j-th candidate location for the i-th net is a weight and may be used to determine matching pairs between the nets and the through-via structures.

In FIG. 5, connection costs with a through-via structure for a certain net (e.g., i-th net) are calculated based on a distance difference in the first horizontal direction HD1, but the manufacturing method of the semiconductor device according to embodiments is not limited thereto. When the candidate locations Tj of the through-via structures THV disposed in the via area VA have coordinate differences in the second horizontal direction HD2, the coordinate diagram of the candidate locations Tj at which the through-via structures THV are disposed in the second horizontal direction HD2 may also be reflected in calculating the connection cost D(i,j) of the through-via structure of the j-th candidate location for the i-th net.

Also, in FIG. 5, by using candidate locations where units that are lower wiring patterns constituting a certain net (e.g., i-th net) of the second semiconductor layer L2 and through-via structures may be placed, connection costs of a through-via structure for a certain net have been calculated, but the method of manufacturing a semiconductor device according to embodiments not limited thereto. Information (e.g., the length of the pattern, the cross-sectional area of the pattern, the material of the pattern, etc.) on an upper wiring pattern constituting a certain net (e.g., i-th net) formed on the first semiconductor layer L1 may also be used to calculate the connection costs.

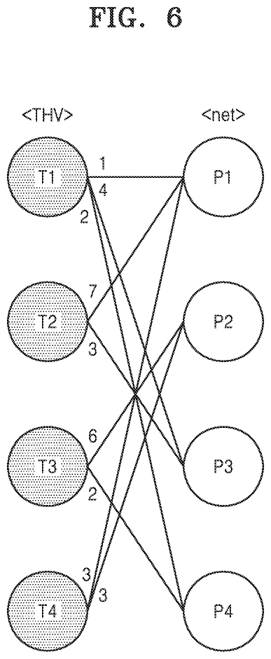

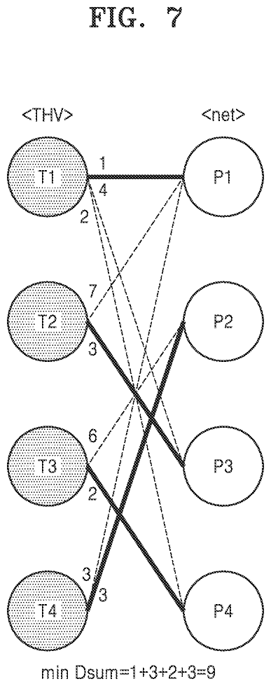

FIGS. 6 and 7 are views for explaining a method for determining optimized matching pairs in operation S30 of FIG. 3.

Referring to FIG. 6, the connection cost of the first net P1 and the through-via structure the first candidate location T1 may be 1, the connection cost of the third net P3 and the through-via structure of the first candidate location T1 may be 4, and the connection cost of the fourth net P4 and the through-via structure of the first candidate location T1 may be 2. The connection cost of the first net P1 and the through-via structures of the second candidate location T2 may be 7, and the connection cost of the third net P3 and the through-via structures of the second candidate location T2 may be 3. The connection cost of the second net P2 and the through-via structures of the third candidate location T3 may be 6, and the connection cost of the fourth net P4 and the through-via structures of the third candidate location T3 is 2. The connection cost of the first net P1 and the through-via structures of the fourth candidate location T4 may be 3, and the connection cost of the second net P2 and the through-via structures of the fourth candidate location T4 may be 3.

Referring to FIG. 7, a sum value obtained by summing connection costs for all nets may be extracted from a matching group consisting of preliminary matching pairs between all nets and through-via structures of candidate locations. For example, according to Equation 2 below, the connection cost D(i,j) of the i-th net and the through-via structure of the j-th candidate location included in the matching group M may be summed over all the nets included in the matching group M, and the sum value Dsum(M) may be calculated.

$${D}_{sum} ( M ) = {\sum }_{( i , j ) ∈ M} D ( i , j ) \qquad [ Equation 2 ]$$

Matching pairs constituting the matching group M having the minimum sum value Dsum(M) among the sum values Dsum(M) calculated according to Equation 2 may be determined. For example, as shown in FIG. 7, a matching group M having 9, which is the minimum sum value min Dsum of sum values Dsum(M), may have the matching pair P1-T1 of the through-via structures of the first candidate location T1 and the first net P1, the matching pair P2-T4 of the through-via structures of the fourth candidate location T4 and the second net P2, the matching pair P3-T2 the through-via structures of the second candidate location T2 and the third net P3, and the matching pair P4-T3 of the through-via structures of the third candidate location T3 and the fourth net P4. As these matching pairs are determined, the first net P1 may be connected to the through-via structure of the first candidate location T1, the second net P2 may be connected to the through-via structure of the fourth candidate location T4, the third net P3 may be connected to the through-via structure of the second candidate location T2, and the fourth net P4 may be connected to the through-via structure of the third candidate location T3.

In an embodiment, a Hungarian algorithm may be used as a method of finding a matching group having a minimum sum value min Dsum among sum values Dsum(M). In the Hungarian algorithm, the location of the through-via structure may correspond to a job in the Hungarian algorithm, a net may correspond to a worker, and a connection cost (e.g., a distance from the net to a through-via structure) may correspond to the cost.

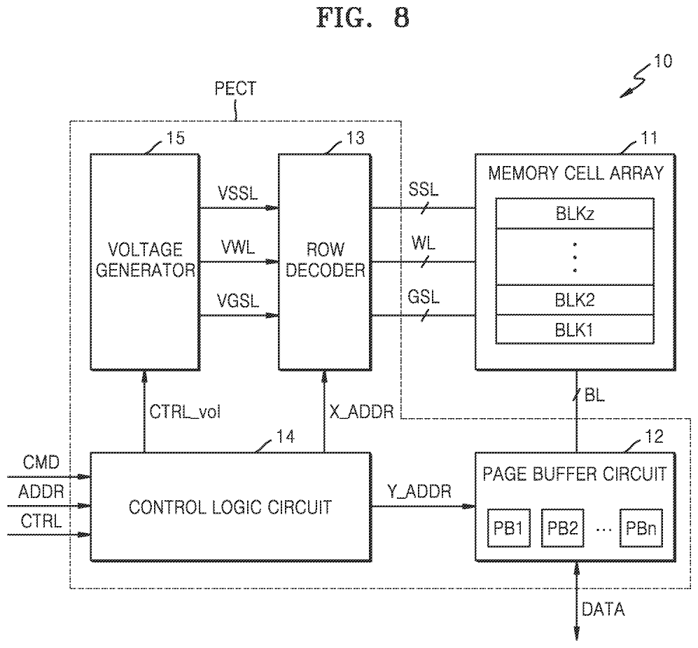

FIG. 8 is a block diagram illustrating a memory device as an example of the semiconductor device 10 according to an embodiment.

Referring to FIGS. 1 and 8, a semiconductor device 10 that is a memory device may include a memory cell array 11 and a peripheral circuit PECT, and the peripheral circuit PECT may include a page buffer circuit 12, a row decoder 13, a control logic circuit 14 and a voltage generator 15. The peripheral circuit PECT may further include a data input/output circuit or an input/output interface. In addition, the peripheral circuit PECT may further include a pre-decoder, a temperature sensor, a command decoder, an address decoder, and the like. In this specification, a memory device may refer to a “nonvolatile memory device”.

The memory cell array 11 may be disposed on the first semiconductor layer L1, and the peripheral circuit PECT may be disposed on the second semiconductor layer L2. Some areas of the peripheral circuit PECT may be buried by the memory cell array 11, and the remaining area of the peripheral circuit PECT may not be buried by the memory cell array 11. In this regard, some areas of the peripheral circuit PECT may overlap in the vertical direction with respect to the memory cell array 11, and the remaining area of the peripheral circuit PECT may not overlap in the vertical direction with respect to the memory cell array 11. However, embodiments are not limited thereto, and at least some of the circuits constituting the row decoder 13 may be disposed on the first semiconductor layer 300.

Accordingly, the memory device may have a structure in which the memory cell array 100 is disposed on the peripheral circuit PECT, that is, a cell on peri (COP) structure. The COP structure may effectively reduce the area in the horizontal direction and improve the degree of integration of the memory device.

The memory cell array 11 may include a plurality of memory blocks BLK1 to BLKz (z is a positive integer), and each of the plurality of memory blocks BLK1 to BLKz may include a plurality of memory cells. The memory cell array 11 may be connected to the page buffer circuit 12 through the bit line BL, and may be connected to the row decoder 13 through the word line WL, the string select line SSL, and the ground select line GSL. For example, the memory cells may be flash memory cells. Hereinafter, embodiments will be described in detail by taking a case where the memory cells are NAND flash memory cells as an example. However, embodiments are not limited thereto, and in some embodiments, the memory cells may be resistive memory cells, such as resistive RAM (ReRAM), phase change RAM (PRAM), or magnetic RAM (MRAM).

In an embodiment, the memory cell array 11 may include a 3D memory cell array, and the 3D memory cell array may include a plurality of NAND strings. Each NAND string may include memory cells connected to word lines vertically stacked on a substrate, which will be described in detail with reference to FIGS. 2 to 3B. For example, the memory cell array 11 may be arranged in a three-dimensional memory array in which a three-dimensional memory array is configured in multiple levels and word lines and/or bit lines are shared between the levels. However, embodiments are not limited thereto, and in some embodiments, the memory cell array 11 may include a two-dimensional memory cell array, and the two-dimensional memory cell array may include a plurality of NAND strings arranged along row and column directions.

The page buffer circuit 12 may include a plurality of page buffers PB1 to PBn (n is a positive integer). Each of the plurality of page buffers PB1 to PBn may be connected to memory cells of the memory cell array 11 through corresponding bit lines. The page buffer circuit 12 may select at least one bit line from among the bit lines BL under the control of the control logic circuit 14. For example, the page buffer circuit 12 may select some of the bit lines BL in response to the column address Y_ADDR received from the control logic circuit 14.

Each of the plurality of page buffers PB1 to PBn may operate as a write driver or a sense amplifier. For example, in a program operation, each of the plurality of page buffers PB1 to PBn may store the data DATA in a memory cell by applying a voltage corresponding to the data DATA to be programmed to a bit line. For example, during a program verify operation or a read operation, each of the plurality of page buffers PB1 to PBn may sense the programmed data DATA by sensing a current or voltage through a bit line.

Based on the command CMD, the address ADDR and the control signal CTRL, the control logic circuit 14 may output various control signals, for example, the voltage control signal CTRL_vol, the row address X_ADDR, and the column address Y_ADDR, for programming data into the memory cell array 11, reading data from the memory cell array 11, or erasing data stored in the memory cell array 11. Accordingly, the control logic circuit 14 may generally control various operations within the memory device. For example, the control logic circuit 14 may receive a command CMD, an address ADDR, and a control signal CTRL from the memory controller.

The voltage generator 15 may generate various types of voltages to perform program, read, and erase operations on the memory cell array 11 based on the voltage control signal CTRL_vol. Specifically, the voltage generator 15 may generate a word line voltage VWL, for example, a program voltage, a read voltage, a pass voltage, an erase verify voltage, or a program verify voltage. Also, the voltage generator 15 may further generate a string select line voltage and a ground select line voltage based on the voltage control signal CTRL_vol.

The row decoder 13 may select one of a plurality of memory blocks BLK1 to BLKz, select one of word lines WL of the selected memory block, and select one of a plurality of string select lines SSL, in response to the row address X_ADDR received from the control logic circuit 14. For example, during a program operation, the row decoder 13 may apply a program voltage and a program verify voltage to a selected word line, and during a read operation, the row decoder 13 may apply a read voltage to the selected word line.

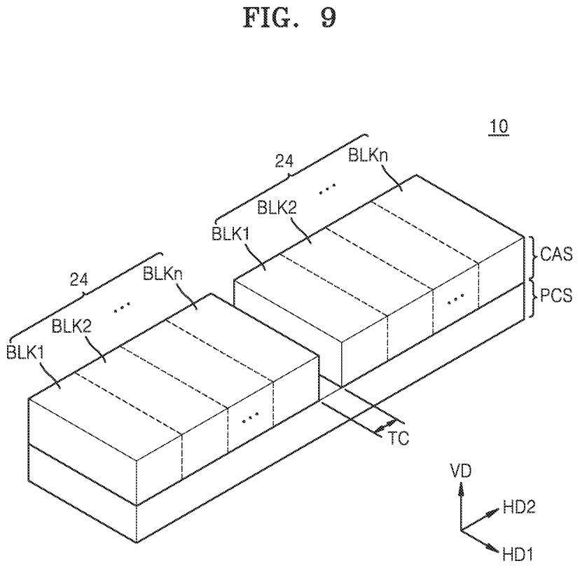

FIG. 9 schematically illustrates a structure of a memory device as an example of a semiconductor device according to an embodiment.

Referring to FIGS. 1 and 9, a semiconductor device 10 that is a memory device includes a cell array structure CAS and a peripheral circuit structure PCS overlapping each other in a vertical direction VD. The cell array structure CAS may include the memory cell array 100 described with reference to FIG. 8 and may be disposed on the first semiconductor layer L1 of FIG. 1. The peripheral circuit structure PCS may include the peripheral circuit 200 described with reference to FIG. 8 and may be disposed on the second semiconductor layer L2 of FIG. 1.

The memory cell array 100 formed on the cell array structure CAS may include a plurality of tiles 24. The plurality of tiles 24 may be divided by the tile cut area TC. Each of the plurality of tiles 24 may include a plurality of memory cell blocks BLK1 to BLKn (n is a positive integer). Each of the plurality of memory cell blocks BLK1 to BLKn may include three-dimensionally arranged memory cells.

In embodiments, two tiles 24 may constitute one mat, but embodiments are not limited thereto. The memory cell array 11 described with reference to FIG. 8 may include a plurality of mats, for example, four mats, but embodiments are not limited thereto.

The via area VA may include the tile cut area TC. That is, through-via structures electrically connecting the cell array structure CAS to the peripheral circuit structure PCS may be formed in the tile cut area TC. For example, through-via structures may be formed to connect the cell array structure CAS and the peripheral circuit structure PCS to each other, or, for example, through-via structures may be formed to connect between the cell array structure CAS and the bonding pad of the first semiconductor layer L1 on which the cell array structure CAS is formed.

The via area VA is not limited to the tile cut area TC. The first semiconductor layer L1 of the memory device may include a central region where the cell array structure CAS is formed and an edge region surrounding the central region. The via area VA may include a tile cut area TC disposed in the central region of the first semiconductor layer L1 of the memory device, and in addition, include at least a portion of an edge region of the first semiconductor layer L1 of the memory device. For example, through-via structures electrically connecting the first semiconductor layer L1 and the second semiconductor layer L2 may be disposed in some regions (e.g., top and bottom regions) of the edge region of the first semiconductor layer L1, and some elements (e.g., a pass transistor that selects each of the word lines WL, the string select line SSL, and the ground select line GSL of the memory cell array (11 of FIG. 8)) of a row decoder (e.g., 13 of FIG. 8) of the memory device may be disposed in other partial regions (e.g., left and right regions) of the edge region.

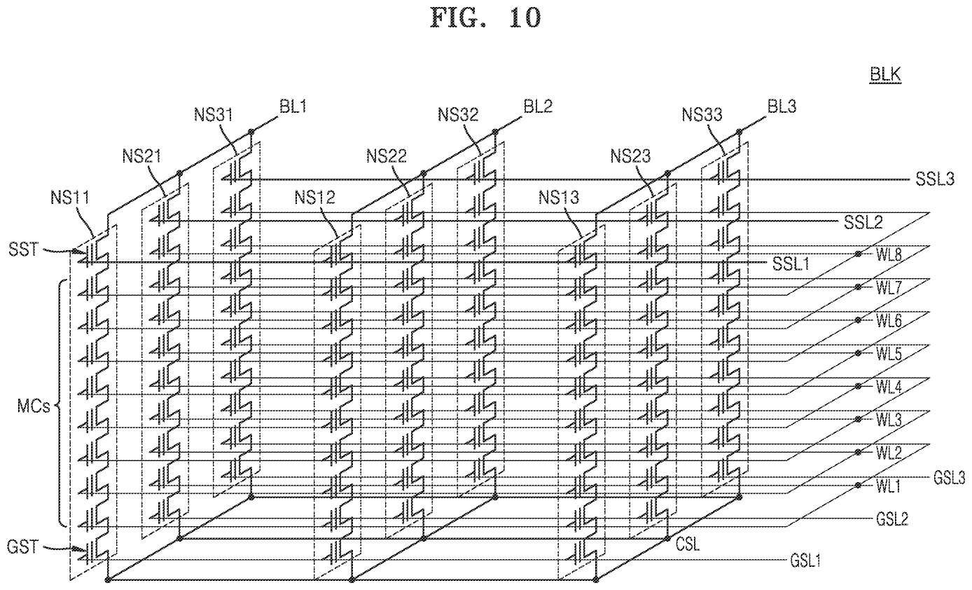

FIG. 10 is a circuit diagram illustrating a memory block BLK according to an embodiment.

Referring to FIG. 10, the memory block BLK may correspond to one of the plurality of memory blocks BLK1 to BLKz of FIG. 8. The memory block BLK includes NAND strings NS11 to NS33, and each NAND string (e.g., NS11) may include a string select transistor SST, a plurality of memory cells MCs, and a ground select transistor GST connected in series. The transistors SST and GST and the memory cells MCs included in each NAND string may form a stacked structure on the substrate in a vertical direction.

The bit lines BL1 to BL3 may extend along a first horizontal direction (e.g., HD1 in FIG. 1), and the word lines WL1 to WL8 may extend along the second horizontal direction (e.g., HD2 of FIG. 1). NAND strings NS11, NS21, and NS31 may be disposed between the first bit line BL1 and the common source line CSL, NAND strings NS12, NS22, and NS32 may be disposed between the second bit line BL2 and the common source line CSL, and NAND strings NS13, NS23, and NS33 may be disposed between the third bit line BL3 and the common source line CSL.

The string select transistor SST may be connected to corresponding string select lines SSL1 to SSL3. The memory cells MCs may be connected to corresponding word lines WL1 to WL8, respectively. The ground select transistor GST may be connected to corresponding ground select lines GSL1 to GSL3. The string select transistor SST may be connected to a corresponding bit line, and the ground select transistor GST may be connected to the common source line CSL. Here, the number of NAND strings, the number of word lines, the number of bit lines, the number of ground select lines, and the number of string select lines may be variously changed according to embodiments.

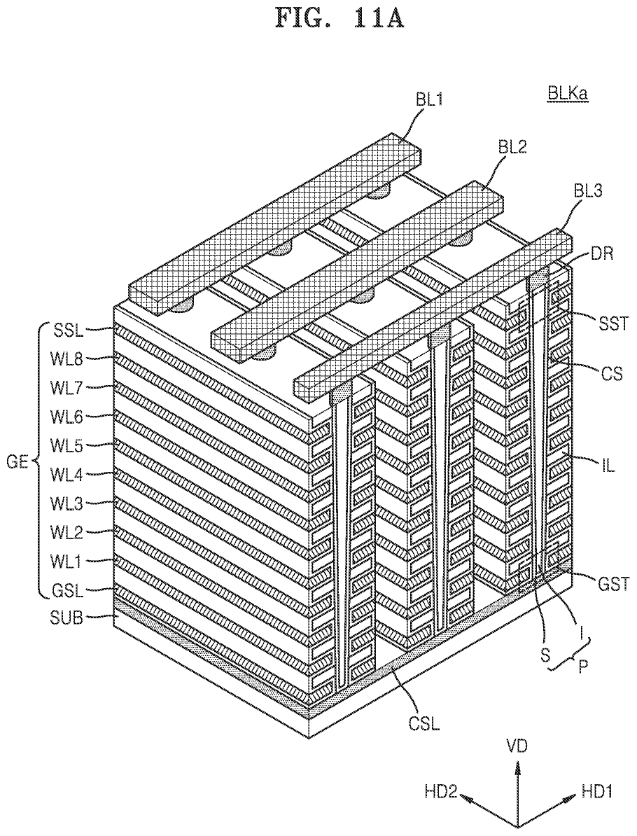

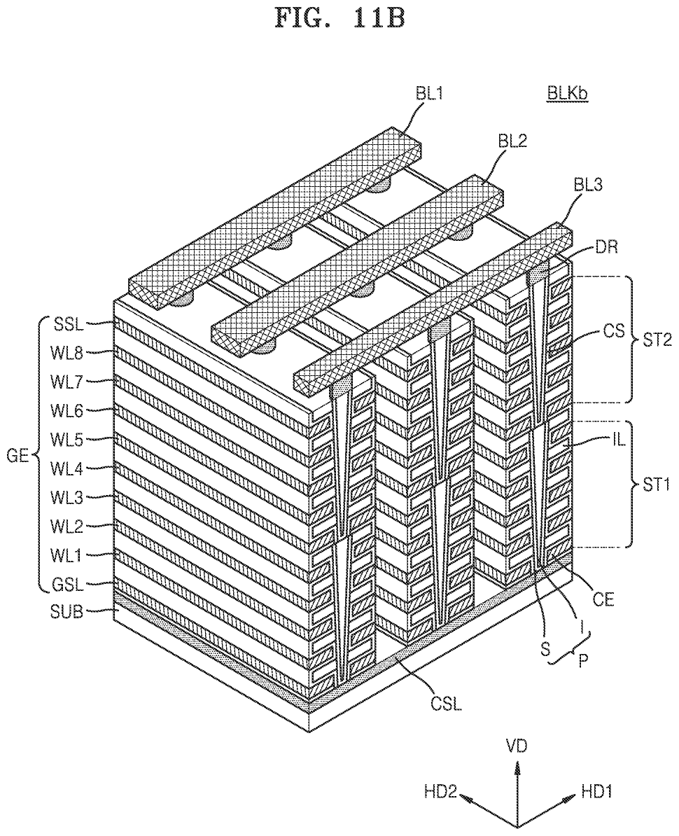

FIG. 11A is a perspective view illustrating a memory block BLKa according to an embodiment.

Referring to FIG. 11A, the memory block BLKa may correspond to one of the plurality of memory blocks BLK1 to BLKz of FIG. 8. The memory block BLKa is formed in a direction VD perpendicular to the substrate SUB. The substrate SUB may have a first conductivity type (e.g., p-type).

In an embodiment, the common source line CSL may be provided on the substrate SUB by being doped with impurities of the second conductivity type (e.g., n-type). In an embodiment, the common source line CSL may be implemented as a conductive layer, such as a metal layer. On the region of the substrate SUB between two adjacent common source lines CSL, a plurality of insulating films IL extending along the second horizontal direction HD2 may be sequentially provided along the vertical direction VD, and the plurality of insulating films IL are spaced apart from each other by a particular distance in the vertical direction VD. For example, the plurality of insulating films IL may include an insulating material, such as silicon oxide.

On the region of the substrate SUB between two adjacent common source lines CSL, a plurality of pillars P sequentially disposed along the first direction or the first horizontal direction HD1 and penetrating the plurality of insulating films IL along the vertical direction VD are provided. For example, the plurality of pillars P may penetrate the plurality of insulating films IL to contact the substrate SUB. Specifically, a surface layer S of each pillar P may include the first type of silicon material and function as a channel region. Accordingly, in some embodiments, the pillar P may be referred to as a channel structure or a vertical channel structure. Meanwhile, the inner layer I of each pillar P may include an insulating material, such as silicon oxide or an air gap.

In a region between two adjacent common source lines CSL, a charge storage layer CS is provided along exposed surfaces of the insulating films IL, the pillars P, and the substrate SUB. The charge storage layer CS may include a gate insulating layer (also referred to as a tunneling insulating layer), a charge trap layer, and a blocking insulating layer. For example, the charge storage layer CS may have an oxide-nitride-oxide (ONO) structure. Also, in a region between two adjacent common source lines CSL, gate electrodes GE, such as select lines GSL and SSL and word lines WL1 to WL8 are provided on the exposed surface of the charge storage layer CS. Drain contacts or drains DR are respectively provided on the plurality of pillars P. For example, the drains DR may include a silicon material doped with impurities of the second conductivity type. Bit lines BL1 to BL3 extending in the first horizontal direction HD1 and spaced apart from each other by a particular distance along the second horizontal direction HD2 are provided on the drains DR.

FIG. 11B is a perspective view illustrating a memory block BLKb according to an embodiment.

Referring to FIG. 11B, the memory block BLKb may correspond to one of the plurality of memory blocks BLK1 to BLKz of FIG. 8. Also, the memory block BLKb corresponds to a modified example of the memory block BLKa of FIG. 11A, and the details described above with reference to FIG. 11A may also be applied to the present embodiment. The memory block BLKb is formed in a direction perpendicular to the substrate SUB. The memory block BLKb may include a first memory stack ST1 and a second memory stack ST2 stacked in the vertical direction VD.

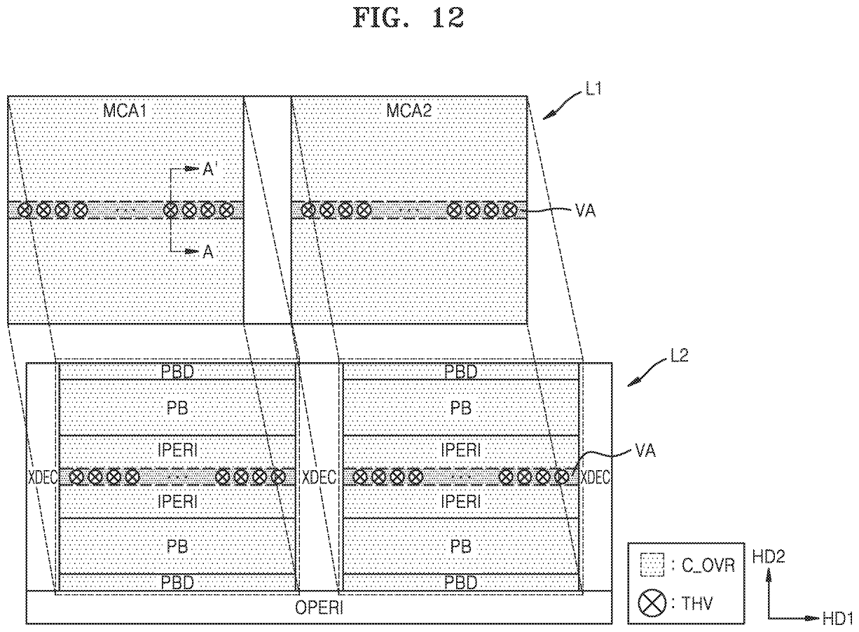

FIG. 12 is a diagram illustrating a memory device that is a semiconductor device according to an embodiment.

Referring to FIG. 12, a semiconductor device 10 that is a memory device includes a first semiconductor layer L1 and a second semiconductor layer L2, and the first semiconductor layer L1 may include memory cell arrays MCA1 and MCA2, and the second semiconductor layer L2 may include peripheral circuits, such as page buffers PB, page buffer decoders PBD, row decoders XDEC, internal peripheral circuits IPERI, and external peripheral circuits OPERI. The second semiconductor layer L2 may further include the control logic circuit 14 of FIG. 8, for example, the control logic circuit may be disposed adjacent to the page buffers PB.

For example, the internal peripheral circuits IPERI may include a voltage generator (e.g., 15 of FIG. 8) that generates a voltage used inside the memory device, and the external peripheral circuit OPERI may include input/output pads for inputting/outputting signals and power pads for receiving power provided to the memory device. The page buffers PB and the page buffer decoders PBD may be included in, for example, the page buffer circuit 12 of FIG. 8, and the row decoders XDEC may be included in, for example, the row decoder 13 of FIG. 8.

An area of the cell region in which the memory cell arrays MCA1 and MCA2 are disposed may be less than that of the first semiconductor layer L1. In an embodiment, an insulating layer may be disposed in a region of the first semiconductor layer L1 in which the memory cell arrays MCA1 and MCA2 are not disposed. In an embodiment, a wiring structure including a plurality of metal layers may be disposed in an area of the first semiconductor layer L1 in which the memory cell arrays MCA1 and MCA2 are not disposed. In an embodiment, some elements of a peripheral circuit (e.g., PECT of FIG. 2) may be disposed in an area of the first semiconductor layer L1 in which the memory cell arrays MCA1 and MCA2 are not disposed.

The memory cell arrays MCA1 and MCA2 may vertically overlap the top of the page buffers PB, page buffer decoders PBD, and internal peripheral circuits IPERI. That is, the page buffers PB, the page buffer decoders PBD, and the internal peripheral circuits IPERI may be disposed in the cell overlap region C_OVR of the second semiconductor layer L2. The row decoders XDEC may not overlap in the vertical direction with respect to the memory cell arrays MCA1 and MCA2. However, unlike shown in FIG. 12, the circuit arrangement of the second semiconductor layer L2 may be variously modified.

Each of the memory cell arrays MCA1 and MCA2 may include a memory plane or a mat MAT. A tile cut area may be formed in each of the memory cell arrays MCA1 and MCA2, and a via area VA may be formed in the tile cut area. The tile cut area is a configuration for separating the memory cell arrays MCA1 and MCA2 from each other in tile units, and an insulating layer may be disposed in the tile cut area, and a wiring structure including a plurality of metal layers may be disposed.

Through-via structures THV electrically connecting the first semiconductor layer L1 to the second semiconductor layer L2 may be disposed in the via area VA. The through-via structures THV may be formed to penetrate the insulating layer of the tile cut area of the first semiconductor layer L1 in a vertical direction. Although FIG. 12 illustrates that the through-via structures THV are directly disposed in the via area VA of the second semiconductor region L2, embodiments are not limited thereto, and bonding pads connected to the through-via structures THV may be disposed in the via area VA of the second semiconductor region L2.

Each of the through-via structures THV may be connected to a net of the second semiconductor layer L2 forming an optimized matching pair according to the method described with reference to FIGS. 3 to 7. Accordingly, in the semiconductor device according to embodiments, because the through-via structures THV connecting the first semiconductor layers L1 to the second semiconductor layers L2 of the stacked structure are disposed in consideration of suitability of routing, degradation of timing characteristics of signals transmitted through the through-via structures THV due to unnecessary detour routing may be prevented.

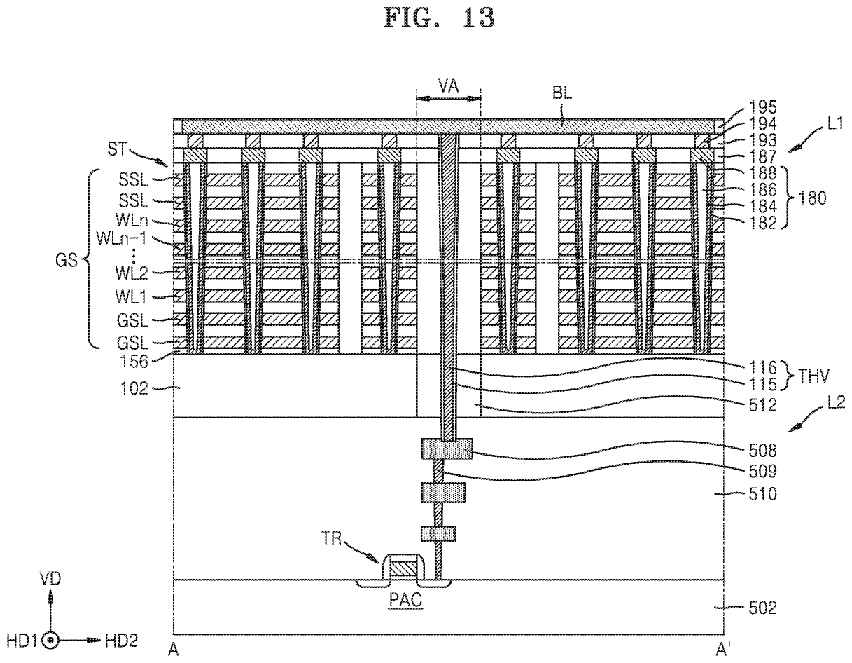

FIG. 13 is a cross-sectional view taken along line A-A′ of FIG. 12.

Referring to FIG. 13, the first semiconductor layer L1 may include a substrate 102 on which a memory cell array is formed. The substrate 102 may include Si, Ge, or SiGe. A memory cell array MCA may be formed on an active area of the memory cell area.

The memory stack ST may include gate lines stacked in a vertical direction. For example, the memory stack ST may include 48, 64, 96, or 128 stacked gate lines, but embodiments are not limited to the above example. The plurality of gate lines included in the gate stack GS may extend in a horizontal direction parallel to the main surface of the substrate 102 and overlap each other in a vertical direction. The gate stack GS may include a plurality of word lines WL1, WL2, . . . , WLn-1, WLn, at least one ground select line GSL, and at least one string select line SSL. FIG. 13 illustrates a case in which the plurality of gate lines GL include two ground select lines GSL and two string select lines SSL, but embodiments are not limited thereto.

Each of the plurality of gate lines included in the gate stack GS may be made of metal, conductive metal nitride, or a combination thereof. For example, each of the plurality of gate lines may be made of tungsten, nickel, cobalt, tantalum, tungsten nitride, titanium nitride, tantalum nitride, or a combination thereof, but embodiments are not limited thereto.

An insulating film 156 may be disposed between the substrate 102 and the ground select line GSL, between a pair of ground select lines GSL, between a plurality of word lines WL1, WL2, . . . , WLn-1, WLn, and between a pair of string select lines SSL. Among the plurality of insulating films 156 on the substrate 102, an insulating film 156 closest to the substrate 102 may have a smaller thickness than other insulating films 156. The plurality of insulating films 156 may be made of silicon oxide, silicon nitride, or SiON.

The plurality of channel structures 180 may extend long in a vertical direction through the gate stack GS and the plurality of insulating films 156. The plurality of channel structures 180 may be arranged spaced apart from each other with a preset interval therebetween along the first horizontal direction HD1 and the second horizontal direction HD2.

Each of the plurality of channel structures 180 may include a gate dielectric film 182, a channel region 184, a filling insulating film 186, and a drain region 188. The channel region 184 may include doped polysilicon and/or undoped polysilicon. The channel region 184 may have a cylindrical shape. An internal space of the channel region 184 may be filled with a filling insulating film 186. The filling insulating film 186 may be made of an insulating material. For example, the filling insulating film 186 may be made of silicon oxide, silicon nitride, SiON, or a combination thereof. In embodiments, the filling insulating film 186 may be omitted, and in this case, the channel region 184 may have a pillar structure without an internal space. The drain region 188 may be formed of impurity-doped polysilicon, metal, conductive metal nitride, or a combination thereof. Examples of metals that may constitute the drain region 188 may include tungsten, nickel, cobalt, and tantalum.

The plurality of drain regions 188 may be insulated from each other by an intermediate insulating film 187. Each of the intermediate insulating films 187 may be formed of an oxide film, a nitride film, or a combination thereof. In FIG. 13, the case where the channel structure 180 includes the gate dielectric film 182 and the gate dielectric film 182 has a shape extending vertically along the channel region 184 is illustrated, but embodiments are not limited thereto, and various modifications and changes are possible.

A through hole may be formed in the substrate 102 in the via area VA. The through hole may be filled with a substrate filling insulating film 512. For example, a plurality of through holes may be formed in the via area VA at candidate locations determined based on routing, degradation of timing characteristics of signals transmitted through corresponding through-via structures THV. The substrate filling insulating film 512 may be formed of a silicon oxide film.

A plurality of through-via structures THV extending in a vertical direction may be disposed in the via area VA of the first semiconductor layer L1. In an embodiment, the via area VA of the first semiconductor layer L1 may be a tile cut area (e.g., TC in FIG. 9).

The plurality of through-via structures THV may penetrate a peripheral interlayer insulating film 510 and a substrate filling insulating film 512 from one peripheral circuit wiring layer 508 selected from among a plurality of peripheral circuit wiring layers 508, and extend in a vertical direction up to the wiring layer of the first semiconductor layer L1. The plurality of through-via structures THV may penetrate the substrate 102 through the through holes and may be surrounded by the substrate filling insulating film 512 within the through holes.

The pattern of the peripheral circuit wiring layer 508 connected to each of the plurality of through-via structures THV may be determined according to a method of forming an optimized matching pair according to the method described in FIGS. 3 to 7. Accordingly, in the semiconductor device according to embodiments, because the through-via structures THV connecting the first semiconductor layers L1 to the second semiconductor layers L2 of the stacked structure are disposed in consideration of suitability of routing, degradation of timing characteristics of signals transmitted through the through-via structures THV due to unnecessary detour routing may be prevented.

Each of the plurality of through-via structures THV may include a contact plug 116 extending in a vertical direction and an insulating plug 115 surrounding the contact plug 116. The contact plug 116 of each of the plurality of through-via structures THV may be connected to the peripheral circuit wiring layer 508 of the second semiconductor layer L2. The peripheral circuit wiring layer 508 may correspond to the lower wiring pattern LWP of FIG. 1. In addition, the contact plug 116 of each of the plurality of through-via structures THV may be connected to a wiring layer of the first semiconductor layer L1, and the wiring layer may correspond to the upper wiring pattern UWP of FIG. 1. For example, the contact plug 116 of each of the plurality of through-via structures THV may be connected to the bit line BL.

The first semiconductor layer L1 may include a plurality of wiring layers, and the plurality of contact plugs 116 and the plurality of wiring layers may each be made of tungsten, titanium, tantalum, copper, aluminum, titanium nitride, tantalum nitride, tungsten nitride, or a combination thereof. The plurality of insulating plugs 115 may be formed of a silicon nitride film, a silicon oxide film, or a combination thereof.

The second semiconductor layer L2 may include a peripheral circuit substrate 502 disposed under the substrate 102 and a plurality of circuits disposed between the peripheral circuit substrate 502 and the substrate 102. Specifically, the plurality of circuits may include a plurality of peripheral transistors TR.

A peripheral circuit active area AC may be defined on the peripheral circuit substrate 502 by a device isolation film. A plurality of peripheral transistors TR may be formed on the peripheral circuit active area PAC. Each of the plurality of peripheral transistors TR may include a peripheral gate and a peripheral source/drain region formed in a peripheral active area PAC at both sides of the peripheral gate. A peripheral interlayer insulating film 510 may be formed on the plurality of peripheral transistors TR. The peripheral interlayer insulating film 510 may include silicon oxide, SiON, SiOCN, or the like.

The second semiconductor layer L2 may include a plurality of peripheral circuit wiring layers 508 and a plurality of peripheral circuit contacts 509. Some of the plurality of peripheral circuit wiring layers 508 may be configured to be electrically connectable to the plurality of peripheral transistors TR. The plurality of peripheral circuit contacts 509 may be configured to interconnect some peripheral circuit wiring layers 508 selected from among the plurality of peripheral circuit wiring layers 508. The plurality of peripheral circuit wiring layers 508 and the plurality of peripheral circuit contacts 509 may be covered with the peripheral interlayer insulating film 510. Some of the plurality of peripheral circuit wiring layers 508 may face the memory stack ST with the substrate 102 therebetween.

The plurality of peripheral circuit wiring layers 508 and the plurality of peripheral circuit contacts 509 may each be made of metal, conductive metal nitride, metal silicide, or a combination thereof. For example, the plurality of peripheral circuit wiring layers 508 and the plurality of peripheral circuit contacts 509 each may include a conductive material, such as tungsten, molybdenum, titanium, cobalt, tantalum, nickel, tungsten silicide, titanium silicide, cobalt silicide, tantalum silicide, nickel silicide, and the like. In FIG. 13, the plurality of peripheral circuit wiring layers 508 are illustrated as having a wiring structure of three layers along a vertical direction, but embodiments are not limited to the illustrated example in FIG. 13. For example, the plurality of peripheral circuit wiring layers 508 may have a multilayer wiring structure of two layers or four layers or more.

FIG. 13 illustrates an example of a semiconductor device in which a plurality of semiconductor layers, that is, a first semiconductor layer L1 and a second semiconductor layer L2, are formed on one semiconductor chip. However, embodiments are not limited thereto, and the first semiconductor layer L1 may constitute one chip, and the second semiconductor layer L2 may constitute another chip, and the semiconductor device may include a plurality of upper bonding pads formed on the first semiconductor layer L1 and connected to the plurality of through-via structures THV, and a lower bonding pad formed on the second semiconductor layer L2 and connected to a plurality of upper bonding pads. For example, the semiconductor device may have a chip to chip (C2C) structure. Here, the C2C structure may refer to a configuration in which the at least one upper chip and the lower chip are connected to each other by a bonding method after fabricating the upper chip of the first semiconductor layer L1 and the lower chip of the second semiconductor layer L2, respectively.

According to an embodiment, the bonding method may include electrically or physically connecting a bonding metal pattern (i.e., upper bonding pad) formed on the uppermost metal layer of an upper chip and a bonding metal pattern (i.e., lower bonding pad) formed on the uppermost metal layer of a lower chip to each other. For example, when the bonding metal patterns are formed of copper (Cu), the bonding method may be a Cu-Cu bonding method. As another example, the bonding metal patterns may also be formed of aluminum (Al) or tungsten (W). For example, when the semiconductor device is a memory device, an upper chip may be inverted and connected to a lower chip through a bonding method.

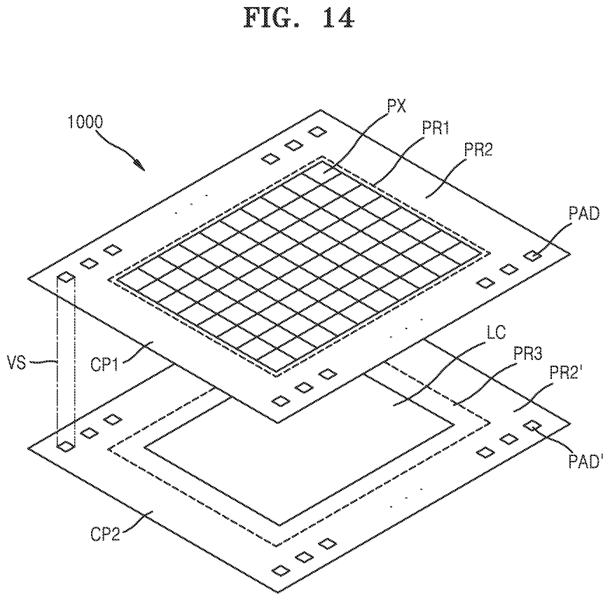

FIG. 14 is a schematic diagram illustrating an image sensor IS as a semiconductor device according to an embodiment.

Referring to FIG. 14, the image sensor IS may be a stacked image sensor including a first chip CP1 and a second chip CP2 stacked in a vertical direction. Although the image sensor IS of FIG. 14 has a structure in which two chips are stacked, embodiments are not limited thereto and the image sensor IS may have a structure in which more than two chips, for example three chips, are stacked.

The first chip CP1 may include a pixel region PR and a pad region PR1, the second chip CP2 may include a peripheral circuit region PR3 and a lower pad region PR2, and a pixel array in which a plurality of pixels PX are disposed may be formed in the pixel region PR1.

The peripheral circuit region PR3 of the second chip CP2 may include a logic circuit block LC and may include a plurality of transistors. The peripheral circuit region PR3 may provide a constant signal to each of the plurality of pixels PX included in the pixel region PR1, and peripheral circuits may be formed to read pixel signals output from each of the plurality of pixels PX. For example, a readout circuit, row driver, a controller, and signal processing unit may be disposed in the peripheral circuit region PR3.

The lower pad region PR2 of the second chip CP2 may include a lower conductive pad PAD′. The lower conductive pad PAD′ may include a plurality of lower conductive pads, which may correspond to the conductive pads PAD, respectively. The lower conductive pad PAD′ may be electrically connected to the conductive pad PAD of the first chip CP1 through the through-via structure VS.

The first chip CP1 may correspond to the first semiconductor layer L1 of FIG. 1, and the second chip CP2 may correspond to the second semiconductor layer L2. The through-via structure VS may correspond to the through-via structure THV of FIG. 1. The net of the peripheral circuit connected to the through-via structure THV may be determined according to the method of forming an optimized matching pair according to the method described in FIGS. 3 to 7. Accordingly, in the semiconductor device according to embodiments, because the through-via structure VS connecting the first chip CP1 to the second chip CP2 is disposed in consideration of the suitability of routing, deterioration of timing characteristics of signals transmitted through the through-via structure VS may be prevented by the necessary detour routing.

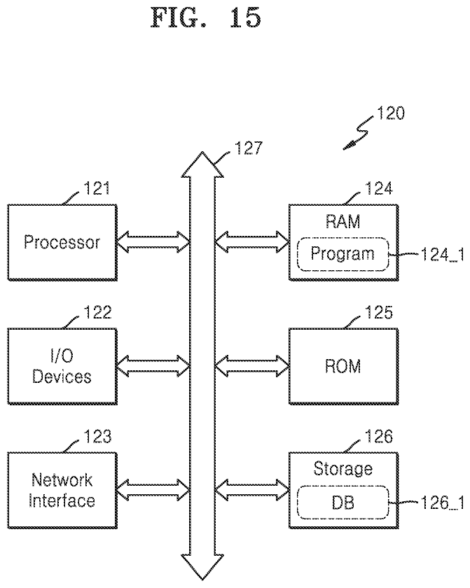

FIG. 15 is a block diagram illustrating a computing system 120 including a memory storing a program according to an embodiment. Operations included in a method for manufacturing a semiconductor device (e.g., operations of FIGS. 3, 4A and 4B) according to embodiments may be performed by the computing system 120.

The computing system 120 may be a fixed computing system, such as a desktop computer, a workstation, a server, and the like and may be a portable computing system, such as a laptop computer. As shown in FIG. 15, the computing system 120 may include a processor 121, input/output (I/O) devices 122, a network interface 123, a random access memory (RAM) 124, a read only memory (ROM) 125, and a storage device 126. The processor 121, the I/O devices 122, the network interface 123, the RAM 124, the ROM 125, and the storage device 126 may be connected to the bus 127, and may communicate with each other through the bus 127.

The processor 121 may be referred to as a processing unit, and for example, may include at least one core capable of executing an arbitrary instruction set (e.g., Intel Architecture-32 (IA-32), 64-bit extension IA-32, x86-64, PowerPC, Sparc, MIPS, ARM, IA-64, and the like), such as a micro-processor, an application processor (AP), a digital signal processor (DSP), and a graphic processing unit (GPU). For example, the processor 121 may access memory, that is, the RAM 124 or the ROM 125 through the bus 127, and may execute instructions stored in the RAM 124 or the ROM 125.

The RAM 124 may store a program 124_1 or at least a part thereof for manufacturing a semiconductor device according to an embodiment, and the program 124_1 may cause the processor 121 to perform at least some of operations included in a method for manufacturing a semiconductor device (e.g., operations of FIGS. 3, 4A, and 4B). That is, the program 124_1 may include a plurality of instructions executable by the processor 121, and a plurality of instructions included in the program 124_1 are executed by the processor 121, such that the processor 121 may perform at least some of operations included in the methods described above with reference to, for example, FIGS. 3, 4A, and 4B.

For example, the processor 121 may define candidate locations where through-via structures may be placed in the via area of the semiconductor device, define nets of the second semiconductor layer to be connected to through-via structures, calculate the connection cost of through-via structures of candidate locations for each of the nets, determine optimized matching pairs between nets and through-via structures of candidate locations based on the calculated concatenation cost, and provide through-via structures corresponding to each of the nets according to the matching pairs. Also, for example, the processor 121 may perform at least one calculation operation of a first calculation operation of calculating the length of routing wiring with through-via structures of candidate locations from each of the nets, a second calculation operation of calculating a resistance value of routing wiring with through-via structures of candidate locations from each of the nets, and a third calculation operation of calculating a timing delay of routing wiring from each of the nets to through-via structures of candidate locations to calculate the connection cost. Processor 121 may determine optimized matching pairs using a Hungarian algorithm stored in the RAM 124.

The storage device 126 may not lose stored data even when the power supplied to the computing system 120 is cut off. For example, the storage device 126 may include a nonvolatile memory device or a storage medium such as a magnetic tape, an optical disk, or a magnetic disk. Further, the storage device 126 may be detachable from the computing system 120. The storage device 126 may store the program 124_1 according to an embodiment, and before the program 124_1 is executed by the processor 121, the program 124_1 or at least a portion thereof may be loaded from the storage device 126 into the RAM 124. Alternatively, the storage device 126 may store a file written in a program language, and the program 124_1 generated by a compiler or the like from a file or at least a part thereof may be loaded into the RAM 124. Also, the storage device 126 may store a database 126_1, and the database 126_1 may include information necessary for designing a semiconductor device.

The storage device 126 may store data to be processed by the processor 121 or data processed by the processor 121. That is, the processor 121 may generate data by processing data stored in the storage device 126 according to the program 124_1 and may store the generated data in the storage device 126. For example, the storage device 126 may store layout data representing connection relationships and arrangements of nets and through-via structures according to matching pairs determined according to the operations performed in FIGS. 3, 4A, and 4B.

The I/O devices 122 may include an input device such as a keyboard and a pointing device, and may include an output device such as a display device and a printer. For example, a user may trigger execution of program 124_1 by processor 121 through the I/O devices 122, input netlist data, and verify layout data representing the placement of nets and through-via structures according to matching pairs determined according to the operations performed in FIGS. 3, 4A and 4B.

The network interface 123 may provide access to a network external to the computing system 120. For example, a network may include multiple computing systems and communication links, and the communication links may include wired links, optical links, wireless links, or any other type of links.

While aspects of embodiments have been particularly shown and described, it will be understood that various changes in form and details may be made therein without departing from the spirit and scope of the following claims.

What is claimed is:

1. A method of manufacturing a semiconductor device including a first semiconductor layer and a second semiconductor layer which are stacked, the method comprising:
identifying candidate locations in a via area of the first semiconductor layer;
identifying nets of the second semiconductor layer to be connected to through-via structures corresponding to the candidate locations;
identifying a plurality of connection costs respectively corresponding to connections between the through-via structures and the nets;
identifying pairs of the nets and the through-via structures, based on the plurality of connection costs;
allocating the through-via structures according to the pairs;
forming the through-via structures at the candidate locations; and
forming electrical connections between the through-via structures and the nets.

2. The method of claim 1, wherein the identifying the plurality of connection costs comprises identifying a plurality of lengths between the nets and the through-via structures.

3. The method of claim 1, wherein the identifying the plurality of connection costs comprises identifying a plurality of resistance values of routing wiring between the nets and the through-via structures.

4. The method of claim 1, wherein the identifying the plurality of connection costs comprises identifying a plurality of timing delays of routing wiring from the nets to the through-via structures of the candidate locations.

5. The method of claim 1, wherein the via area extends longer in a first horizontal direction than in a second horizontal direction perpendicular to the first horizontal direction,
wherein the candidate locations are sequentially provided along the first horizontal direction, and
wherein the identifying the plurality of connection costs comprises identifying first connection costs between a first net among the nets and the through-via structures according to coordinates in the first horizontal direction of the first net and coordinates in the first horizontal direction of each of the candidate locations.

6. The method of claim 1, wherein the identifying the pairs comprises:
identifying matching groups, each including preliminary matching pairs between each of the nets and the through-via structures;
extracting sum values obtained by summing the connection costs for each of the nets in each of the matching groups; and
identifying matching pairs between the nets and the through-via structures included in a matching group having a minimum sum value among the sum values as the pairs.

7. The method of claim 1, wherein the identifying the pairs is performed using a Hungarian algorithm.

8. The method of claim 1, wherein the semiconductor device is a memory device, and
wherein the method further comprises:
forming a memory cell array on the first semiconductor layer; and
forming a peripheral circuit on the second semiconductor layer.

9. The method of claim 8, wherein the memory cell array comprises a plurality of tiles,
wherein the plurality of tiles are separated from each other by a tile cut area formed in the first semiconductor layer, and
wherein the via area comprises the tile cut area.

10. The method of claim 1, wherein the semiconductor device is implemented as a single semiconductor chip.

11. The method of claim 1, wherein the first semiconductor layer is implemented as a first semiconductor chip, and the second semiconductor layer is implemented as a second semiconductor chip.

12. A method of manufacturing a semiconductor device including a through-via structure connecting an upper wiring pattern and a lower wiring pattern, which constitute a first net, to each other, the method comprising:
identifying candidate locations in a via area of the semiconductor device;
identifying nets to be connected to through-via structures corresponding to the candidate locations;
identifying a plurality of connection costs respectively corresponding to connections between the through-via structures and the nets;
identifying pairs of the nets and the through-via structures, based on the plurality of connection costs; and
forming the through-via structures to connect the upper wiring pattern and the lower wiring pattern to each other according to the pairs.

13. The method of claim 12, wherein the identifying the plurality of connection costs comprises identifying a plurality of lengths between the nets and the through-via structures.

14. The method of claim 12, wherein the identifying the plurality of connection costs comprises identifying a plurality of resistance values of routing wiring between the nets and the through-via structures.

15. The method of claim 12, wherein the via area extends longer in a first horizontal direction than in a second horizontal direction perpendicular to the first horizontal direction, and
wherein the candidate locations are sequentially provided along the first horizontal direction.

16. The method of claim 12, wherein the semiconductor device is a memory device comprising a first semiconductor layer with the upper wiring pattern and a second semiconductor layer with the lower wiring pattern, and
wherein the method further comprises forming a memory cell array on the first semiconductor layer, and a peripheral circuit on the second semiconductor layer.

17. The method of claim 16, wherein the memory cell array comprises a plurality of tiles,
wherein the plurality of tiles are separated from each other by a tile cut area formed in the first semiconductor layer, and
wherein the via area comprises the tile cut area.

18. The method of claim 17, further comprising forming an insulating layer separating the plurality of tiles from each other in the tile cut area, and
wherein the through-via structure is formed to pass through the insulating layer in a vertical direction.

19. A computing system for manufacturing a semiconductor device including a first semiconductor layer and a second semiconductor layer, which are stacked, the computing system comprising:
a memory storing a program; and
a processor configured to access the memory and execute the program to control the computing system to:
identify candidate locations in a via area of the first semiconductor layer;
identify nets of the second semiconductor layer to be connected to through-via structures corresponding to the candidate locations;
identify a plurality of connection costs respectively corresponding to connections between the through-via structures and the nets;
identify pairs of the nets and the through-via structures, based on the plurality of connection costs;
allocate the through-via structures according to the pairs;
form the through-via structures at the candidate locations; and
form electrical connections between the through-via structures and the nets.

20. The computing system of claim 19, wherein the processor is further configured to execute the program to control the computing system to perform at least one calculation operation from among:
a first calculation operation of calculating a plurality of lengths between the nets and the through-via structures,
a second calculation operation of calculating a plurality of resistance values of routing wiring between the nets and the through-via structures, and
a third calculation operation of calculating a plurality of timing delays of routing wiring from the nets to the through-via structures.
